(19) United States
(12) Patent Application Publication
(10) Pub. No.: US 2025/0201635 A1
(43) Pub. Date: Jun. 19, 2025

(54) SUBSTRATE PROCESSING APPARATUS AND SUBSTRATE PROCESSING METHOD

(71) Applicant: EBARA CORPORATION, Tokyo (JP)

(72) Inventors: Issei SUGANO, Tokyo (JP); Teruaki HOMBO, Tokyo (JP)

(21) Appl. No.: 18/979,173

(22) Filed: Dec. 12, 2024

(30) Foreign Application Priority Data
Dec. 18, 2023 (JP) 2023-213176

(51) Int. Cl. H01L 21/66; H01L 21/67

(52) U.S. Cl. CPC H01L 22/12; H01L 21/67051; H01L 21/67219; H01L 21/67288

(57) ABSTRACT

A substrate processing apparatus capable of determining a shape abnormality of a wafer is disclosed. The substrate processing apparatus includes: a shape detection module for detecting a signal corresponding to a surface shape of a substrate; and a controller for determining a shape abnormality of the substrate.

### CROSS REFERENCE TO RELATED APPLICATION

This document claims priority to Japanese Patent Application No. 2023-213176 filed Dec. 18, 2023, the entire contents of which are hereby incorporated by reference.

### BACKGROUND

A substrate processing apparatus for processing a substrate, such as wafer, is known in the art. In such substrate processing apparatus, a wafer is transferred to various processing modules and processed in each processing module.

A surface of a wafer may have a shape abnormality, such as chipped portion, deformation (e.g., warp, distortion), etc. When the wafer is processed in each processing module, the shape abnormality may occur in the surface of the wafer.

When a wafer having such a shape abnormality is transported, a transfer robot cannot transport the wafer appropriately, which may result in a wafer transport error. When a wafer having such a shape abnormality is processed in the processing module, the wafer may be damaged due to the shape abnormality. When such a problem occurs, the substrate processing apparatus must be temporarily stopped, resulting in a significant decrease in wafer throughput.

### SUMMARY

Therefore, there are provided a substrate processing apparatus and a substrate processing method capable of determining shape abnormality of a wafer.

Embodiments, which will be described below, relate to a substrate processing apparatus and a substrate processing method.

In an embodiment, there is provided a substrate processing apparatus comprising: a processing module configured to process a substrate; a transfer robot configured to transport the substrate to the processing module; a shape detection module configured to detect a signal corresponding to a surface shape of the substrate held by the transfer robot, the shape detection module being coupled to the transfer robot and configured to detect the signal above the transfer robot; and a controller configured to determine a shape abnormality of the substrate based on the signal detected by the shape detection module.

In an embodiment, the shape detection module includes: a detection sensor disposed above the substrate held by the transfer robot; and a sensor-moving actuator configured to move the detection sensor along a movement path on a surface of the substrate.

In an embodiment, the transfer robot is configured to rotate the substrate, and the shape detection module includes: a fixed sensor disposed above a periphery of the substrate held by the transfer robot; a movable sensor configured to be movable in a direction parallel to the substrate held by the transfer robot; and a sensor-moving actuator configured to move the movable sensor forward and backward from the periphery to a center of the substrate.

In an embodiment, the shape detection module is configured to detect the signal when the transfer robot is transporting the substrate.

In an embodiment, the shape detection module comprises a first shape detection module, the transfer robot comprises a first transfer robot, the first transfer robot is configured to transport the substrate to a polishing module, the substrate processing apparatus comprises: a second transfer robot configured to transport the substrate polished by the polishing module to a cleaning module; and a second shape detection module coupled to the second transfer robot and configured to detect a signal corresponding to the surface shape of the substrate held by the second transfer robot.

In an embodiment, the first shape detection module and the second shape detection module are configured to detect the shape of the same surface of the substrate.

In an embodiment, the substrate processing apparatus further comprises a fluid ejection device disposed on a transport path for the substrate between the polishing module and the cleaning module, the fluid ejection device including a fluid ejection nozzle configured to spray compressed fluid onto a surface of the substrate that is to be detected by the second shape detection module.

In an embodiment, the controller is configured to: acquire shape information of the substrate to be determined for the shape abnormality based on the signal acquired from the shape detection module; and compare the acquired shape information with a predetermined judgment criterion to determine the shape abnormality.

In an embodiment, the controller is configured to: create a normal distribution from a plurality of values calculated based on a plurality of signals previously acquired from the shape detection module; and determine, as the judgment criterion, a range of ±Xσ from a mean value of the normal distribution.

In an embodiment, there is provided a substrate processing method comprising:
detecting, by a shape detection module, a signal corresponding to a surface shape of a substrate held by a transfer robot that transports the substrate to a processing module, the shape detection module being coupled to the transfer robot and arranged to detect the signal from above the transfer robot; and determining a shape abnormality of the substrate based on the signal detected by the shape detection module.

In an embodiment, the shape detection module includes: a detection sensor; and a sensor-moving actuator configured to move the detection sensor, wherein the detection sensor is disposed above the substrate held by the transfer robot, and the sensor-moving actuator moves the detection sensor along a movement path on a surface of the substrate.

In an embodiment, the shape detection module includes: a fixed sensor and a movable sensor; and a sensor-moving actuator configured to move the movable sensor forward and backward from a periphery of the substrate to a center of the substrate, wherein the sensor-moving actuator moves the movable sensor forward and backward from the periphery to the center of the substrate while the substrate is being rotated by the transfer robot.

In an embodiment, the signal is detected by the shape detection module while the substrate is being transported by the transfer robot.

In an embodiment, the shape detection module comprises a first shape detection module, the transfer robot comprises a first transfer robot, the substrate is transported to a polishing module by the first transfer robot, the substrate polished by the polishing module is transported to a cleaning module by a second transfer robot, a second shape detection module detects a signal corresponding to the surface shape of the substrate held by the second transfer robot, and the second shape detection module is coupled to the second transfer robot.

In an embodiment, the first shape detection module and the second shape detection module detect the shape of the same surface of the substrate.

In an embodiment, the substrate processing method further comprises spraying, by a fluid ejection device, a compressed fluid onto a surface of the substrate that is to be detected by the second shape detection module, the fluid ejection device being disposed on a transport path for the substrate between the polishing module and the cleaning module.

In an embodiment, the substrate processing method further comprises: acquiring shape information of the substrate to be determined for the shape abnormality based on the signal acquired from the shape detection module; and comparing the acquired shape information with a predetermined judgment criterion to determine the shape abnormality.

In an embodiment, the substrate processing method further comprises: creating a normal distribution from a plurality of values calculated based on a plurality of signals previously acquired from the shape detection module; and determining, as the judgment criterion, a range of ±Xσ from a mean value of the normal distribution.

The shape detection module detects a signal corresponding to the shape of the substrate, and the controller determines the shape abnormality of the substrate based on the signal. Therefore, the substrate processing apparatus does not temporarily stop due to a problem, such as substrate transport error, and as a result, a wafer throughput can be improved.

### BRIEF DESCRIPTION OF THE DRAWINGS

FIG. 1 is a plan view showing an embodiment of a substrate processing apparatus;

FIG. 2A is a plan view showing a cleaning section;

FIG. 2B is a side view showing the cleaning section;

FIG. 3 is a perspective view showing an embodiment of a shape detection module;

FIG. 4 is a diagram showing a movement path of a detection sensor;

FIG. 5 is a diagram showing a flowchart for determining shape abnormality of a wafer by a controller;

FIG. 6 is a perspective view showing the shape detection module coupled to a transfer robot;

FIG. 7 is a plan view of FIG. 6;

FIG. 8 is a diagram showing a detection trajectory of a movable sensor;

FIG. 9 is a diagram showing a flowchart for determining shape abnormality of a wafer by the controller;

FIG. 10 is a perspective view showing an embodiment of a fluid ejection device;

FIGS. 11A and 11B are diagrams showing ejection ports formed in a fluid ejection nozzle;

FIGS. 12A to 12C are diagrams showing a wafer when transported from a polishing section to the cleaning section; and

FIG. 13 is a diagram showing a retrieve window through which a temporary placement table can be accessed.

### DESCRIPTION OF EMBODIMENTS

Hereinafter, embodiments will be described with reference to the drawings. In the drawings described below, the same or corresponding components are denoted by the same reference numerals, and duplicated descriptions will be omitted. In the multiple embodiments described below, configuration of an embodiment that is not particularly described is the same as that of other embodiments, and duplicated descriptions will be omitted.

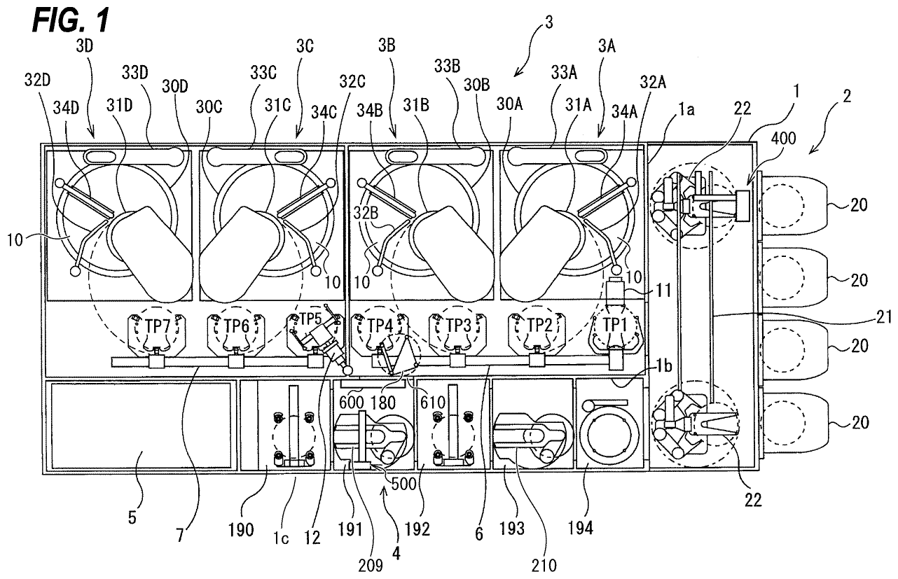

FIG. 1 is a plan view showing an embodiment of a substrate processing apparatus. As shown in FIG. 1, the substrate processing apparatus includes a rectangular housing 1. An inside of the housing 1 is divided by partition walls 1a and 1b into a loading-unloading section 2, a polishing section 3, and a cleaning section 4.

The loading-unloading section 2, the polishing section 3, and the cleaning section 4 are assembled independently and evacuated independently. The substrate processing apparatus includes a controller 5 configured to control substrate processing operation. The loading-unloading section 2 includes two or more (four in this embodiment) front load units 20 on which wafer cassettes for storing a large number of wafers (substrates) therein are placed.

The front load units 20 are disposed adjacent to the housing 1 and are arranged along a width direction (direction perpendicular to a longitudinal direction) of the substrate processing apparatus. An open cassette, a Standard Manufacturing Interface (SMIF) pod, or a Front Opening Unified Pod (FOUP) can be mounted on each front load unit 20. Each of SMIF and FOUP is an airtight container that can store the wafer cassette therein and can maintain an environment independent of an external space by covering the wafer cassette with a partition wall.

In the loading-unloading section 2, a moving mechanism 21 is disposed along an arrangement direction of the front load units 20. Two transfer robots (loaders) 22 that can move along the arrangement direction of the wafer cassettes are installed on the moving mechanism 21. Each transfer robot 22 can access the wafer cassettes mounted to the front load units 20 by moving on the moving mechanism 21.

The polishing section 3 is an area where polishing (planarization) of a wafer is performed. The polishing section 3 includes a first polishing module 3A, a second polishing module 3B, a third polishing module 3C, and a fourth polishing module 3D. The first polishing module 3A, the second polishing module 3B, the third polishing module 3C, and the fourth polishing module 3D are arranged along the longitudinal direction of the substrate processing apparatus, as shown in FIG. 1.

As shown in FIG. 1, the first polishing module 3A includes a polishing table 30A on which a polishing pad 10 having a polishing surface is attached, a top ring 31A for holding a wafer and polishing the wafer while pressing the wafer against the polishing pad 10 on the polishing table 30A, a polishing-liquid supply nozzle 32A for supplying a polishing liquid or a dressing liquid (e.g., pure water) onto the polishing pad 10, a dresser 33A for dressing the polishing surface of the polishing pad 10, and an atomizer 34A for spraying a fluid mixture of liquid (e.g., pure water) and gas (e.g., nitrogen gas) or liquid (e.g., pure water) in a mist onto the polishing surface.

Similarly, the second polishing module 3B includes a polishing table 30B to which a polishing pad 10 is attached, a top ring 31B, a polishing-liquid supply nozzle 32B, a dresser 33B, and an atomizer 34B. The third polishing module 3C includes a polishing table 30C to which a polishing pad 10 is attached, a top ring 31C, a polishing-liquid supply nozzle 32C, a dresser 33C, and an atomizer 34C. The fourth polishing module 3D includes a polishing table 30D on which a polishing pad 10 is attached, a top ring 31D, a polishing-liquid supply nozzle 32D, a dresser 33D, and an atomizer 34D.

A transport mechanism for transporting a wafer will now be described. As shown in FIG. 1, the substrate processing apparatus includes a first linear transporter 6 disposed adjacent to the first polishing module 3A and the second polishing module 3B. The first linear transporter 6 is a mechanism configured to transport a wafer between four transfer positions (first transfer position TP1, second transfer position TP2, third transfer position TP3, and fourth transfer position TP4) which are arranged along an arrangement direction of the polishing modules 3A and 3B.

The substrate processing apparatus includes a second linear transporter 7 disposed adjacent to the third polishing module 3C and the fourth polishing module 3D. The second linear transporter 7 is a mechanism for transporting a wafer between three transfer positions (a fifth transfer position TP5, a sixth transfer position TP6, and a seventh transfer position TP7) which are arranged along an arrangement direction of the polishing modules 3C and 3D.

A wafer is transported to the polishing modules 3A and 3B by the first linear transporter 6. The top ring 31A of the first polishing module 3A moves between a polishing position and the second transfer position TP2 by a swing motion of the top ring 31A. Therefore, the wafer is transferred to and from the top ring 31A at the second transfer position TP2.

Similarly, the top ring 31B of the second polishing module 3B moves between a polishing position and the third transfer position TP3, and a wafer is transferred to and from the top ring 31B at the third transfer position TP3. The top ring 31C of the third polishing module 3C moves between a polishing position and the sixth transfer position TP6, and a wafer is transferred to and from the top ring 31C at the sixth transfer position TP6. The top ring 31D of the fourth polishing module 3D moves between a polishing position and the seventh transfer position TP7, and a wafer is transferred to and from the top ring 31D at the seventh transfer position TP7.

At the first transfer position TP1, a lifter 11 is disposed for receiving a wafer from the transfer robot 22. The wafer is delivered from the transfer robot 22 to the first linear transporter 6 via the lifter 11.

The substrate processing apparatus includes a shutter (not shown) provided on the partition wall 1a. The shutter is disposed between the lifter 11 and the transfer robot 22. When a wafer is transported, the shutter is opened and the wafer is transferred from the transfer robot 22 to the lifter 11. A swing transporter 12 is disposed between the first linear transporter 6, the second linear transporter 7, and the cleaning section 4.

The swing transporter 12 has a hand that is movable between the fourth transfer position TP4 and the fifth transfer position TP5. Transferring of a wafer from the first linear transporter 6 to the second linear transporter 7 is performed by the swing transporter 12. The wafer is transported to the third polishing module 3C and/or the fourth polishing module 3D by the second linear transporter 7. The wafer that has been polished in the polishing section 3 is transported to the cleaning section 4 via the swing transporter 12.

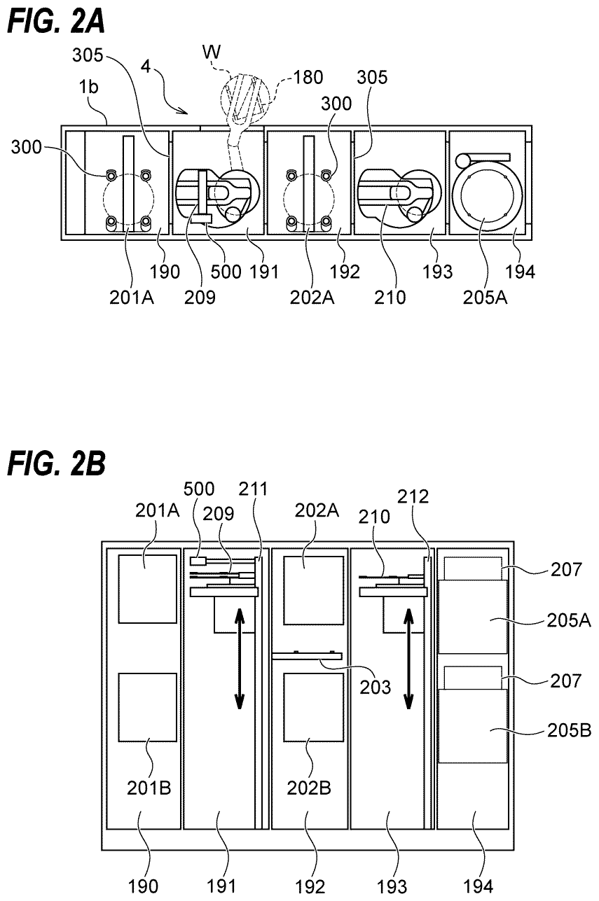

FIG. 2A is a plan view showing the cleaning section, and FIG. 2B is a side view showing the cleaning section. As shown in FIG. 2A and FIG. 2B, the cleaning section 4 is divided into a first cleaning chamber 190, a first transfer chamber 191, a second cleaning chamber 192, a second transfer chamber 193, and a drying chamber 194. In the first cleaning chamber 190, an upper primary cleaning module 201A and a lower primary cleaning module 201B are arranged along the vertical direction.

The upper primary cleaning module 201A is disposed above the lower primary cleaning module 201B. Similarly, in the second cleaning chamber 192, an upper secondary cleaning module 202A and a lower secondary cleaning module 202B are arranged along the vertical direction. The upper secondary cleaning module 202A is disposed above the lower secondary cleaning module 202B. The primary and secondary cleaning modules 201A, 201B, 202A, and 202B are cleaning devices that clean a wafer using a cleaning liquid.

A temporary placement table 203 for a wafer is provided between the upper secondary cleaning module 202A and the lower secondary cleaning module 202B. An upper drying module 205A and a lower drying module 205B are arranged along the vertical direction in the drying chamber 194. The upper drying module 205A and the lower drying module 205B are isolated from each other.

Filter fan devices 207, 207 for supplying clean air into the drying modules 205A, 205B, respectively, are provided on the top of the upper drying module 205A and the top of the lower drying module 205B.

A first transfer robot 209 capable of moving up and down is disposed in the first transport chamber 191, and a second transfer robot 210 capable of moving up and down is disposed in the second transport chamber 193. The first transfer robot 209 and the second transfer robot 210 are movably supported by support shafts 211 and 212, respectively, extending in the vertical direction. The first transfer robot 209 and the second transfer robot 210 are movable up and down

along the support shafts 211, 212. As indicated by dotted line in FIG. 2A, the first transfer robot 209 is disposed in a position accessible to the temporary placement table 180. When the first transfer robot 209 accesses the temporary placement table 180, a shutter 610 (described in detail later) provided on the partition wall 1b opens.

The first transfer robot 209 is operable to transport the wafer W between the temporary placement table 180, the upper primary cleaning module 201A, the lower primary cleaning module 201B, the temporary placement table 203, the upper secondary cleaning module 202A, and the lower secondary cleaning module 202B.

The second transfer robot 210 is operable to transport the wafer W between the upper secondary cleaning module 202A, the lower secondary cleaning module 202B, the temporary placement table 203, the upper drying module 205A, and the lower drying module 205B.

The transfer robot 22 shown in FIG. 1 removes the wafer W from the upper drying module 205A or the lower drying module 205B and returns the wafer W to the wafer cassette. When the transfer robot 22 accesses the drying modules 205A and 205B, a shutter (not shown) provided in the partition wall 1a is opened. In this manner, the wafer W is transported through the loading-unloading section 2, the polishing section 3, and the cleaning section 4 in this order.

The wafer W may have shape abnormality, such as chipped portion or deformation (e.g., warp or distortion) in its surface. In this case, when the wafer W having the shape abnormality is transported from the front load unit 20 to the polishing section 3, the transfer robot 22 may not be able to transport the wafer W appropriately, and a transport error of the wafer W may occur.

When the wafer W is processed in each processing module (in this embodiment, the polishing modules 3A to 3D of the polishing section 3, the cleaning modules 201A, 201B, 202A, 202B of the cleaning section 4, etc.), the shape abnormality may occur in the surface of the wafer W. In this case also, the first transfer robot 209 may not be able to properly transport the wafer W, thus resulting in a transport error of the wafer W. Such a transport error of the wafer W may cause a decrease in throughput of the wafer W.

Therefore, the substrate processing apparatus includes a shape detection module configured to determine the shape abnormality of the wafer W when held by the transfer robot. Configuration of the shape detection module will be described below with reference to the drawings.

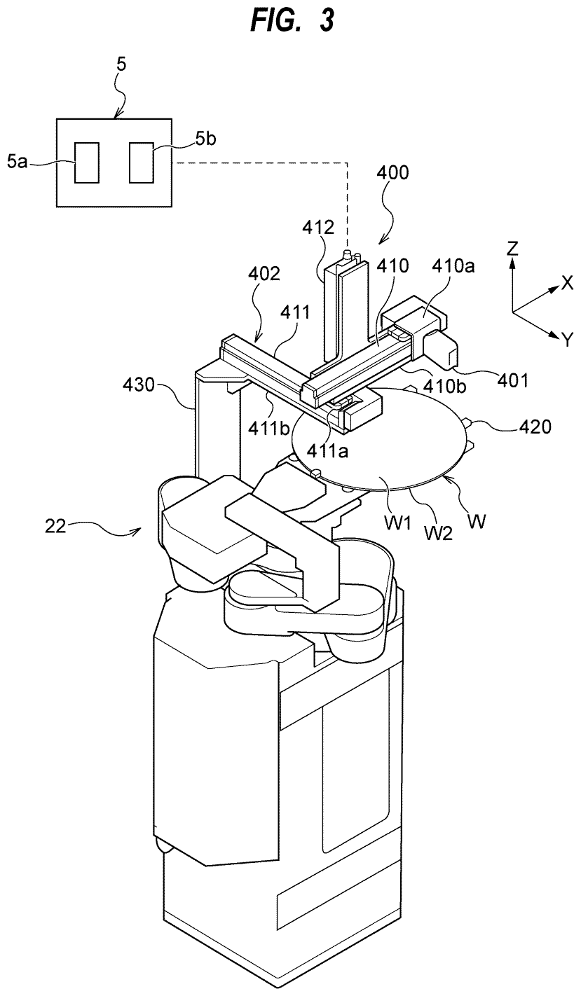

FIG. 3 is a perspective view of an embodiment of a shape detection module 400. In the embodiment shown in FIG. 3, the shape detection module 400 is configured to detect a signal corresponding to a shape (surface shape) of the wafer W held by a robot hand 420 of the transfer robot 22. The controller 5 is configured to determine the presence or absence of the shape abnormality of the wafer W based on the signal detected by the shape detection module 400.

As shown in FIG. 3, the controller 5 includes a memory 5a in which programs are stored, and an arithmetic device 5b configured to execute arithmetic operations according to instructions included in the programs. The memory 5a includes a main memory, such as a RAM, and an auxiliary memory, such as a hard disk drive (HDD) or a solid state drive (SSD). Examples of the arithmetic device 5b include a CPU (Central Processing Unit) and a GPU (Graphics Processing Unit).

As shown in FIG. 3, the shape detection module 400 is coupled to the transfer robot 22. The shape detection module 400 is configured to detect the signal corresponding to the shape of the wafer W above the robot hand 420 of the transfer robot 22. The shape detection module 400 includes a detection sensor 401 disposed above the wafer W on the robot hand 420, and a sensor-moving actuator 402 configured to move the detection sensor 401.

The wafer W has a first surface W1 and a second surface W2 at the opposite side from the first surface W1. The first surface W1 is, for example, a surface to be polished of the wafer W, and in this case, the second surface W2 is a back surface of the wafer W.

In this embodiment, the detection sensor 401 faces the first surface W1, while in an embodiment, the detection sensor 401 may face the second surface W2. Hereinafter, in this specification, the first surface W1 and the second surface W2 may be referred to as a front surface without any particular limitation to the first surface W1 or the second surface W2.

In this embodiment, the detection sensor 401 is an optical sensor (e.g., a laser displacement meter) configured to emit light to the surface of the wafer W and detect reflected light from the wafer W. In this case, the detection sensor 401 detects the signal corresponding to a distance between the detection sensor 401 and the surface of the wafer W.

The controller 5 is electrically coupled to the shape detection module 400. Therefore, the controller 5 coupled to the detection sensor 401 is configured to acquire the signal detected by the detection sensor 401 and determine the presence or absence of the shape abnormality of the wafer W based on the signal acquired.

The sensor-moving actuator 402 is configured to move the detection sensor 401 in a direction parallel to the surface of the wafer W held by the robot hand 420. The direction parallel to the surface of the wafer W is an X-axis direction and a Y-axis direction which are perpendicular to each other. A direction perpendicular to the surface of the wafer W is a Z-axis direction.

The sensor-moving actuator 402 includes a first translation actuator 410 and a second translation actuator 411 which are configured to move the detection sensor 401 in the direction parallel to the surface of the wafer W.

In this embodiment, the first translation actuator 410 is configured to move the detection sensor 401 in the X-axis direction. The second translation actuator 411 is configured to move the detection sensor 401 in the Y-axis direction.

Hereinafter, in this specification, the first translation actuator 410 may be referred to as X-axis actuator 410, and the second translation actuator 411 may be referred to as Y-axis actuator 411.

In this embodiment, each of the X-axis actuator 410 and the Y-axis actuator 411 has a linear guide structure. More specifically, the X-axis actuator 410 includes a moving element 410a that is movable in the X-axis direction, and a guide rail 410b configured to guide the movement of the moving element 410a in the X-axis direction.

The detection sensor 401 is attached to the moving element 410a. Therefore, when the moving element 410a moves in the X-axis direction along the guide rail 410b, the detection sensor 401 attached to the moving element 410a moves in the X-axis direction together with the moving element 410a.

The Y-axis actuator 411 has a configuration similar to the X-axis actuator 410. More specifically, the Y-axis actuator 411 includes a moving element 411a that is movable in the Y-axis direction, and a guide rail 411b configured to guide the movement of the moving element 411a in the Y-axis direction.

The X-axis actuator 410 (and the detection sensor 401) is attached to the moving element 411a. Therefore, when the moving element 411a moves in the Y-axis direction along the guide rail 411b, the X-axis actuator 410 attached to the moving element 411a moves in the Y-axis direction together with the moving element 411a. The detection sensor 401 attached to the moving element 410a of the X-axis actuator 410 moves in the Y-axis direction together with the moving element 411a.

The shape detection module 400 includes a coupling member 430 that couples the sensor-moving actuator 402 to the transfer robot 22. The coupling member 430 extends in the Z-axis direction and is coupled to the Y-axis actuator 411 (more specifically, the guide rail 411b). The sensor-moving actuator 402 coupled to the coupling member 430 positions the detection sensor 401 above the surface of the wafer W.

As shown in FIG. 3, the sensor-moving actuator 402 includes a vertically-moving actuator 412 configured to move the detection sensor 401 in the Z-axis direction. Hereinafter, in this specification, the vertically-moving actuator 412 may be referred to as Z-axis actuator (elevating actuator) 412.

Although a detailed description of structure of the Z-axis actuator 412 will be omitted, the Z-axis actuator 412 may be, for example, an air cylinder or a ball-screw mechanism (a combination of a servo motor and a ball screw).

In this embodiment, the Z-axis actuator 412 is supported on the guide rail 411b of the Y-axis actuator 411 via the moving element 411a such that the Z-axis actuator 412 is movable in the Y-axis direction. The X-axis actuator 410 and the detection sensor 401 are attached to the Z-axis actuator 412. Therefore, when the Z-axis actuator 412 is in motion, the detection sensor 401 moves together with the X-axis actuator 410 toward or away from the surface of the wafer W.

In this manner, the controller 5 can operate the sensor-moving actuator 402 (i.e., the translation actuators 410, 411 and the vertically-moving actuator 412) to move the detection sensor 401 in the X-axis direction, the Y-axis direction, and the Z-axis direction.

When the transfer robot 22 accesses a wafer W in the wafer cassette and/or when the transfer robot 22 accesses the lifter 11, the detection sensor 401 may come into contact with the wafer W. Therefore, when the transfer robot 22 transports the wafer W, the controller 5 operates the Z-axis actuator 412 to move the detection sensor 401 to a predetermined retreat position. The retreat position is a position where the detection sensor 401 is separated from the robot hand 420 in the Z-axis direction. With this configuration, the transfer robot 22 can prevent the detection sensor 401 from coming into contact with the wafer W when transporting the wafer W.

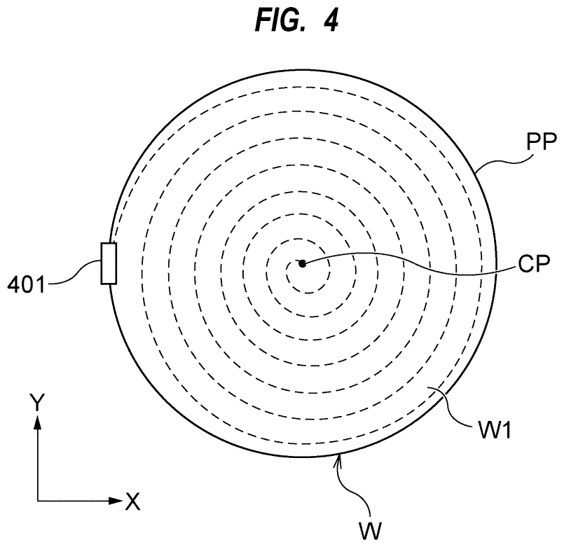

FIG. 4 is a diagram showing a movement path of the detection sensor 401. As shown in FIG. 4, the sensor-moving actuator 402 is configured to move the detection sensor 401 along a spiral movement path (i.e., a detection path) on the surface of the wafer W (the first surface W1 in FIG. 4). In other words, the controller 5 operates the X-axis actuator 410 and the Y-axis actuator 411 to thereby move the detection sensor 401 along the spiral movement path. Data corresponding to the movement path of the detection sensor 401 is stored in the memory 5a.

The detection sensor 401 moves spirally along the predetermined movement path from a periphery PP of the wafer W toward a center CP of the wafer W, and continuously detects the signal corresponding to the distance between the detection sensor 401 and the surface of the wafer W. In this manner, the detection sensor 401 is moved in the direction parallel to the surface of the wafer W, while the detection sensor 401 detects the signal corresponding to the shape of the entire surface of the wafer W.

In one embodiment, the sensor-moving actuator 402 may move the detection sensor 401 spirally from the center CP toward the periphery PP. In one embodiment, as long as the detection sensor 401 can detect the signal corresponding to the shape of the entire surface of the wafer W, the sensor-moving actuator 402 does not necessarily have to move the detection sensor 401 spirally.

The detection sensor 401 detects the signal corresponding to the shape of the wafer W, and then outputs the signal to the controller 5. The controller 5 receives the signal detected by the detection sensor 401, and acquires (measures) shape information of the wafer W that is to be judged for the shape abnormality based on the signal. The controller 5 then compares the acquired shape information with a predetermined judgment criterion to determine whether or not the wafer W has the shape abnormality.

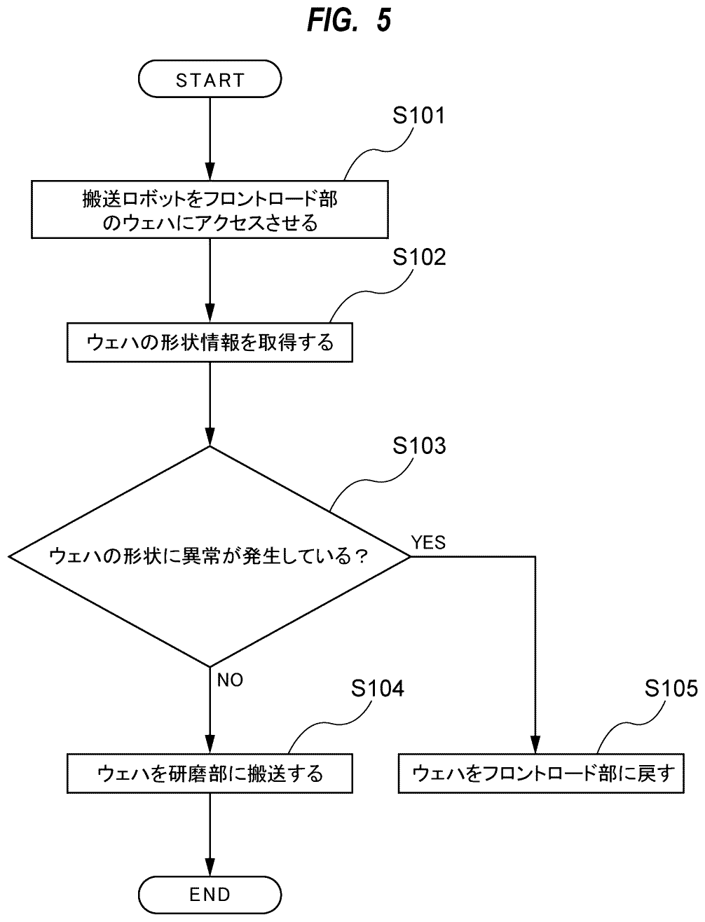

FIG. 5 is a diagram showing a flowchart of determining the shape abnormality of the wafer by the controller. As shown in step S101 of FIG. 5, first, the controller 5 instructs the transfer robot 22 to access the wafer W in the front load unit 20 and hold the wafer W on the robot hand 420. At this time, the controller 5 operates the Z-axis actuator 412 to elevate the detection sensor 401 to the predetermined retreat position so that the detection sensor 401 does not come into contact with the wafer W.

Thereafter, the controller 5 operates the Z-axis actuator 412 to lower the detection sensor 401 to a predetermined detection position. The detection position is a position where the detection sensor 401 is located near the wafer W on the robot hand 420.

After the controller 5 moves the detection sensor 401 to the detection position, the controller 5 operates the X-axis actuator 410 and the Y-axis actuator 411 to move the detection sensor 401 along the predetermined movement path. The detection sensor 401 detects the signal corresponding to the shape of the wafer W while moving along the movement path. After the detection sensor 401 detects the signal, the controller 5 operates the Z-axis actuator 412 to move the detection sensor 401 to the predetermined retract position again.

In an embodiment, the controller 5 may instruct the detection sensor 401 to perform the signal detection operation when the transfer robot 22 is transporting the wafer W from a predetermined receiving position (in this embodiment, the front load unit 20) to a predetermined transfer position (in this embodiment, the lifter 11).

With such a configuration, the controller 5 can improve the throughput of the wafer W. If the shape detection module 400 is disposed away from the transfer robot 22, the controller 5 must transport the transfer robot 22 holding the wafer W all the way to the location of the shape detection module 400, which results in a waste of time.

In this embodiment, the shape detection module 400 is coupled to the transfer robot 22. Therefore, when the wafer W is being transported by the transfer robot 22, the detection sensor 401 can detect the signal corresponding to the shape of the wafer W. In this manner, in this embodiment, the substrate processing apparatus can simultaneously perform the transporting of the wafer W and the signal detection operation, thereby improving the throughput of the wafer W.

After the step S101 in FIG. 5, the controller 5 acquires the shape information of the wafer W based on the signal detected by the detection sensor 401 (see step S102), and determines whether or not the wafer W has the shape abnormality (see step S103).

Examples of the shape abnormality of the wafer W include a chipped portion in the periphery PP of the wafer W and deformation of the surface of the wafer W. For example, the controller 5 can determine the presence or absence of a chipped portion in the periphery PP of the wafer W based on the detected signal in the periphery PP of the wafer W.

When there is a chipped portion in the periphery PP of the wafer W, the detection sensor 401 does not detect reflected light at the chipped portion even if the detection sensor 401 emits the light to the entire circumference of the periphery PP. In other words, the detection sensor 401 detects different signals in the entire circumference of the periphery PP. Therefore, the controller 5 can determine the chipped portion in the periphery PP of the wafer W based on the signal detected by the detection sensor 401.

When the deformation occurs in the wafer W, the detection sensor 401 moving along the movement path detects signals of different magnitudes in a region between the periphery PP and the center CP. Therefore, the controller 5 can determine the deformation of the wafer W based on the signal detected by the detection sensor 401.

The memory 5a stores data indicating the judgment criterion to be compared with the shape information of the wafer W. The controller 5 compares the acquired shape information of the wafer W with the predetermined judgment criterion to determine the shape abnormality of the wafer W.

For example, the controller 5 determines whether or not a value (which is the shape information of the wafer W) calculated based on the signal detected by the detection sensor 401 exceeds a threshold value as the judgment criterion. This calculated value is a numerical value (amount of displacement) indicating a difference in distance between the detection sensor 401 and the surface of the wafer W in a region between the periphery PP and the center CP.

In one embodiment, before processing of the wafer W, the controller 5 calculates a plurality of displacement amounts (numerical values) based on a plurality of signals previously acquired from the detection sensor 401. The controller 5 may create a normal distribution from the plurality of calculated values and determine a range of ±Xσ (standard deviation) as the judgment criterion from an average of the normal distribution. Here, “X” represents a predetermined coefficient. For example, the controller 5 may determine a range of ±3σ (standard deviation) as the judgment criterion (i.e., an acceptable range) from the average of the normal distribution.

The controller 5 compares the shape information of the wafer W with the predetermined judgment criterion, and if the controller 5 determines that no abnormality has occurred in the shape of the wafer W (see “NO” in step S103), the controller 5 instructs the transfer robot 22 to transport the wafer W to the polishing section 3 (see step S104).

On the other hand, when the controller 5 determines that an abnormality has occurred in the shape of the wafer W (see “YES” in step S103), the controller 5 instructs the transfer robot 22 to return the wafer W to the front load unit 20 (step S105). Since multiple wafers W in the front load unit 20 are tagged, the transfer robot 22 will not receive the wafer W having the shape abnormality again.

According to this embodiment, the shape detection module 400 is coupled to the transfer robot 22. Therefore, the controller 5 can determine the shape abnormality of the wafer W immediately after the wafer W is transported to the loading-unloading section 2 of the substrate processing apparatus. Therefore, the substrate processing apparatus can minimize a risk of transporting the wafer W having the shape abnormality to the processing module.

When the controller 5 determines that the wafer W has a shape abnormality, the controller 5 may store, in the memory 5a, data on the shape abnormality as information for determining the judgment criterion. By storing such data, the controller 5 can more accurately determine the judgment criterion based on the stored data.

The wafer W that has been transported to the polishing section 3 by the transfer robot 22 is polished in any one of the polishing modules 3A to 3D of the polishing section 3 (see FIG. 1), and then transported to the cleaning section 4 by the first transfer robot 209. The polishing of the wafer W may cause a shape abnormality in the wafer W.

Therefore, the substrate processing apparatus includes a shape detection module for determining a shape abnormality of the wafer W held by the first transfer robot 209. Hereinafter, in this specification, the first transfer robot 209 may be simply referred to as transfer robot 209.

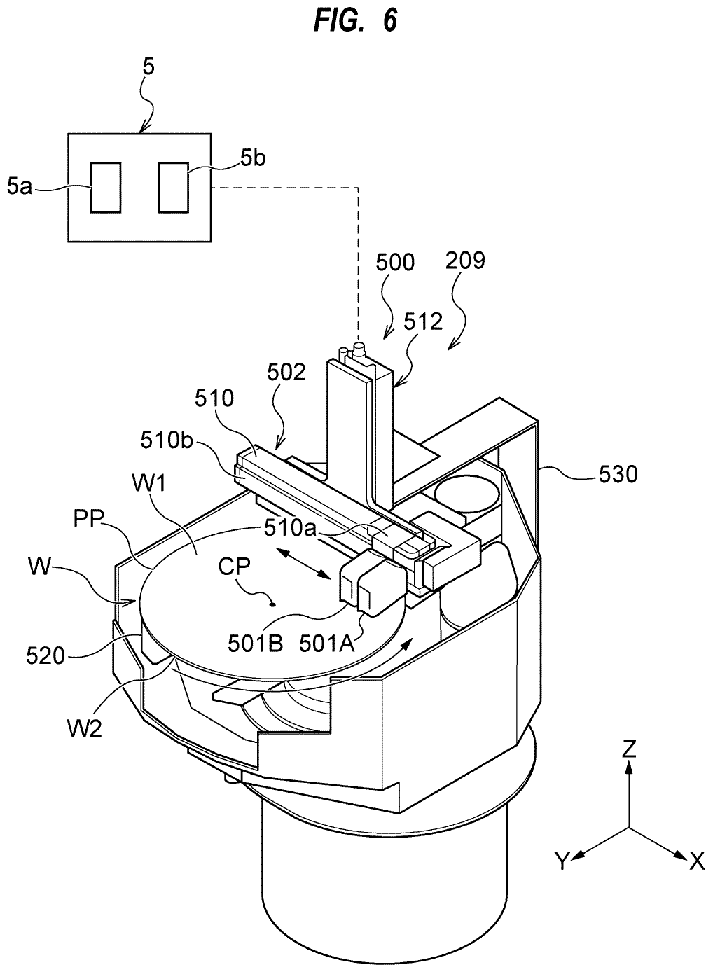

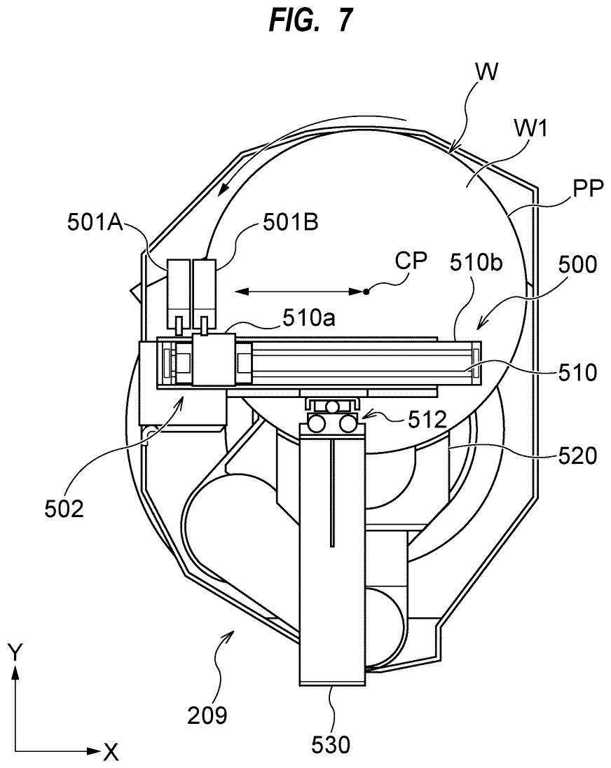

FIG. 6 is a perspective view showing a shape detection module coupled to the transfer robot, and FIG. 7 is a plan view of FIG. 6. In the embodiment shown in FIGS. 6 and 7, the substrate processing apparatus includes a shape detection module 500 coupled to the transfer robot 209.

The shape detection module 500 includes a fixed sensor 501A arranged above the periphery PP of the wafer W held by a robot hand 520 of the transfer robot 209, a movable sensor 501B movable in a direction parallel to the wafer W held by the transfer robot 209 (i.e., in X-axis direction or Y-axis direction), and a sensor-moving actuator 502 configured to move the movable sensor 501B forward and backward from the periphery PP to the center CP.

The fixed sensor 501A and the movable sensor 501B are disposed adjacent to each other at a position above the surface of the wafer W. In this embodiment, the fixed sensor 501A and the movable sensor 501B have the same structure. For example, each of the fixed sensor 501A and the movable sensor 501B is an optical sensor (e.g., a laser displacement meter) configured to emit light to the surface of the wafer W and detect reflected light from the wafer W.

In the embodiment shown in FIG. 7, the fixed sensor 501A and the movable sensor 501B are disposed adjacent to each other near the periphery PP of the wafer W. In one embodiment, the movable sensor 501B may be disposed at a distance from the fixed sensor 501A. In that case, the movable sensor 501B is configured to be movable to an outermost edge of the wafer W (including the periphery PP) without contacting the fixed sensor 501A.

The sensor-moving actuator 502 includes a translation actuator 510 configured to move the movable sensor 501B in a direction parallel to the surface of the wafer W, and a vertically-moving actuator (i.e., a Z-axis actuator) 512 configured to move the fixed sensor 501A and the movable sensor 501B in the Z-axis direction together with the translation actuator 510.

In this embodiment, the horizontally-moving actuator 510 has a linear guide structure and is configured to move the movable sensor 501B in the X-axis direction. Therefore, hereinafter in this specification, the horizontally-moving actuator 510 may be referred to as X-axis actuator 510. In an embodiment, the horizontally-moving actuator 510 may be configured to move the movable sensor 501B in the Y-axis direction.

The Z-axis actuator 512 has the same structure as the Z-axis actuator 412. The Z-axis actuator 512 may be, for example, an air cylinder or a ball screw mechanism (a combination of a servo motor and a ball screw).

The X-axis actuator 510 includes a moving element 510a that is movable in the X-axis direction (i.e., a direction parallel to the surface of the wafer W), and a guide rail 510b configured to guide the movement of the moving element 510a in the X-axis direction.

The movable sensor 501B is attached to the moving element 510a. Therefore, when the moving element 510a moves in the X-axis direction along the guide rail 510b, the movable sensor 501B attached to the moving element 510a moves in the X-axis direction together with the moving element 510a.

The shape detection module 500 includes a coupling member 530 that couples the sensor moving actuator 502 to the transfer robot 209. The coupling member 530 extends in the Z-axis direction, similar to the coupling member 430, and is coupled to the Z-axis actuator 512. The sensor moving actuator 502 coupled to the coupling member 530 can position the fixed sensor 501A and the movable sensor 501B above the surface of the wafer W.

When the Z-axis actuator 512 is in motion, the fixed sensor 501A and the movable sensor 501B move together with the X-axis actuator 510 toward or away from the surface of the wafer W.

The controller 5 is electrically coupled to the shape detection module 500. Therefore, the controller 5 can operate the Z-axis actuator 512 to move the fixed sensor 501A and the movable sensor 501B in the Z-axis direction, and can operate the X-axis actuator 510 to move the movable sensor 501B in the X-axis direction.

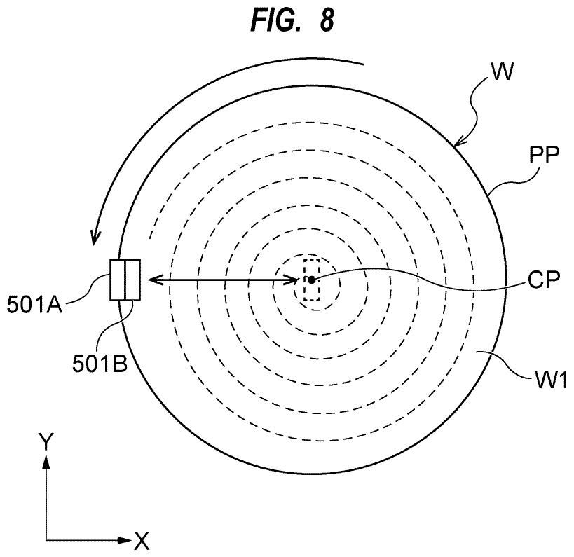

FIG. 8 is a diagram showing a detection path of the movable sensor. In this embodiment, the transfer robot 209 is configured to rotate the wafer W held by the robot hand 520. Therefore, when the X-axis actuator 510 moves the movable sensor 501B linearly from the periphery PP to the center CP of the wafer W while the transfer robot 209 rotates the wafer W, the movable sensor 501B detects a signal corresponding to the shape of the wafer W along a spiral detection path.

The fixed sensor 501A is disposed above the periphery PP of the wafer W. Therefore, when the transfer robot 209 rotates the wafer W, the fixed sensor 501A detects the signal corresponding to the shape of the periphery PP without no movement of the fixed sensor 501A.

In this way, the controller 5 acquires the shape information of the wafer W for the shape abnormality based on the signals detected by the fixed sensor 501A and the movable sensor 501B, and compares the acquired shape information with the predetermined judgment criterion to determine the shape abnormality of the wafer W.

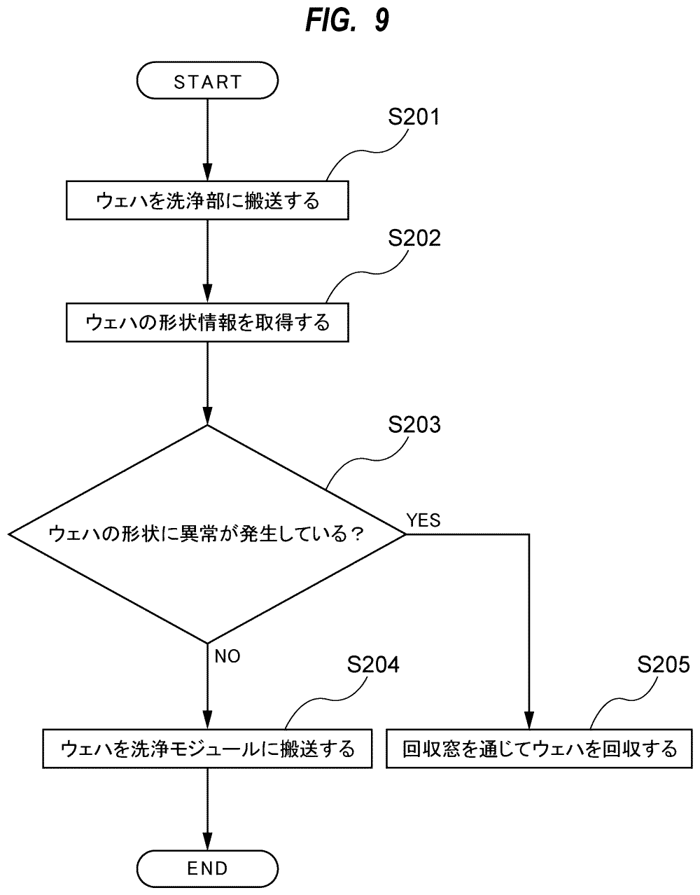

FIG. 9 is a diagram showing a flowchart of determining the shape abnormality of the wafer by the controller. First, a polished wafer W is placed on the temporary placement table 180. The first transfer robot 209 accesses the wafer W on the temporary placement table 180 and transports the wafer W to the cleaning section 4 (see step S201).

The surface of the polished wafer W may be wet with the liquid used in the polishing process of the wafer W. In this embodiment, each of the fixed sensor 501A and the movable sensor 501B is an optical sensor. Therefore, if the surface of the wafer W is wet, each of the fixed sensor 501A and the movable sensor 501B may not be able to accurately detect the signal corresponding to the shape of the wafer W. Therefore, the substrate processing apparatus includes a fluid ejection device configured to remove the liquid from the surface of the wafer W to be transported to the cleaning section 4. Configuration of the fluid ejection device will be described below with reference to the drawings.

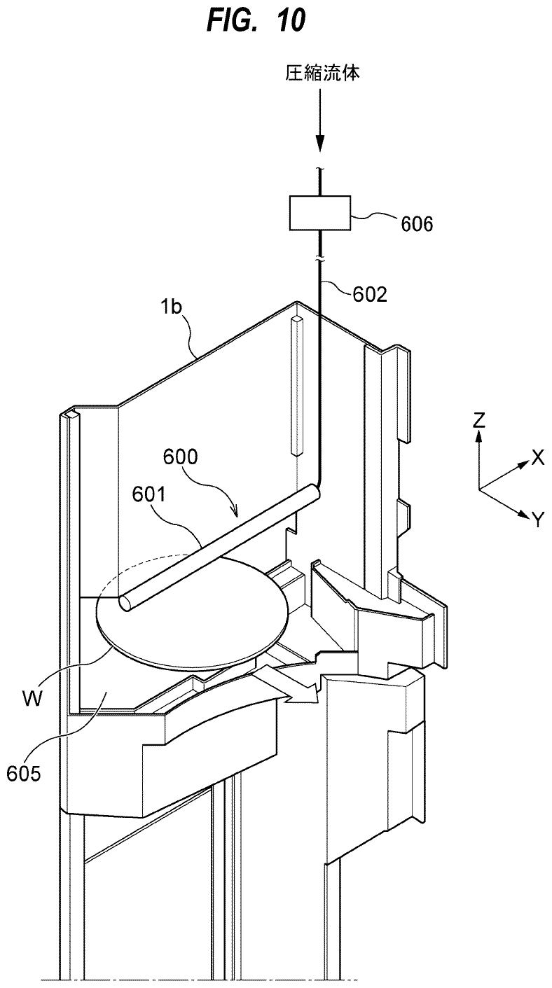

FIG. 10 is a perspective view showing an embodiment of the fluid ejection device. As shown in FIG. 10, the substrate processing apparatus includes a fluid ejection device 600 disposed on a transport path for the wafer W between the polishing section 3 and the cleaning section 4.

The fluid ejection device 600 includes a fluid ejection nozzle 601 configured to spray compressed fluid onto the surface of the wafer W (more specifically, the surface to be detected by the shape detection module 500), and a fluid supply line 602 coupled to the fluid ejection nozzle 601.

The fluid supply line 602 is coupled to a compressed-fluid supply source (not shown), and the compressed fluid supplied from the compressed-fluid supply source is introduced into the fluid ejection nozzle 601 through the fluid supply line 602. Examples of the compressed fluid include compressed air and compressed gas (e.g., an inert gas, such as nitrogen gas).

In one embodiment, the fluid ejection device 600 may include a filter 606 disposed upstream of the fluid ejection nozzle 601 in a flow direction of the compressed fluid. In the embodiment shown in FIG. 10, the filter 606 is attached to the fluid supply line 602. The filter 606 is configured to remove foreign matter contained in the compressed fluid flowing through the fluid supply line 602. With this configuration, clean compressed fluid can be sprayed onto the surface of the wafer W through the fluid ejection nozzle 601.

As shown in FIG. 10, the fluid ejection nozzle 601 is disposed above a transfer opening 605 formed in the partition wall 1b. The fluid ejection nozzle 601 has a cylindrical shape and extends along a longitudinal direction of the transfer opening 605.

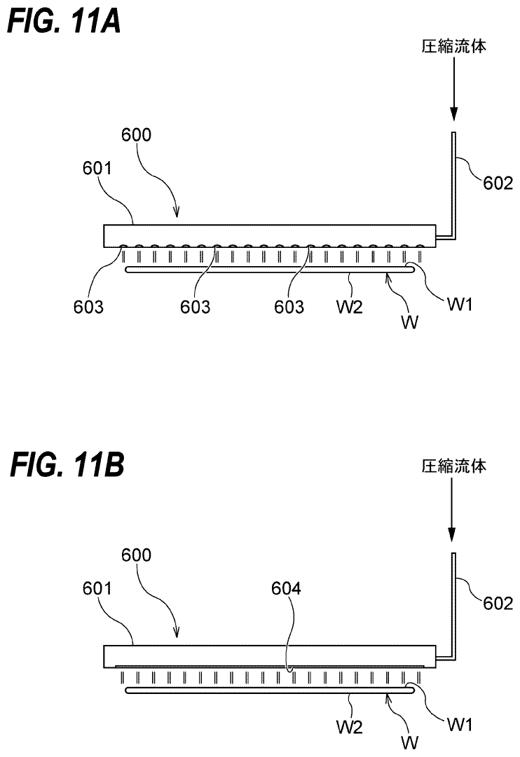

FIGS. 11A and 11B are diagrams showing ejection ports formed in the fluid ejection nozzle. In the embodiment shown in FIG. 11A, the fluid ejection nozzle 601 has a plurality of ejection ports 603 arranged along the longitudinal direction of the fluid ejection nozzle 601. The plurality of ejection ports 603 are arranged so as to face the surface of the wafer W (the first surface W1 in FIG. 11A). Therefore, the compressed fluid introduced into the fluid ejection nozzle 601 is sprayed onto the surface of the wafer W through the plurality of ejection ports 603.

The fluid ejection nozzle 601 has a length longer than the diameter of the wafer W. The length of the multiple ejection ports 603 extending in the longitudinal direction of the fluid ejection nozzle 601 (i.e., a distance between the ejection port 603 on one end side and the ejection port 603 on the other end side) is longer than the diameter of the wafer W. Therefore, the compressed fluid supplied from the multiple ejection ports 603 is sprayed onto the entire surface of the wafer W.

As shown in FIG. 11B, the fluid ejection nozzle 601 may have a single slit-shaped ejection port 604 extending along the longitudinal direction of the fluid ejection nozzle 601. In this configuration, the ejection port 604 is disposed so as to the front surface of the wafer W. The length of the ejection port 604 is longer than the diameter of the wafer W. Therefore, the compressed fluid supplied from the ejection port 604 is sprayed onto the entire surface of the wafer W.

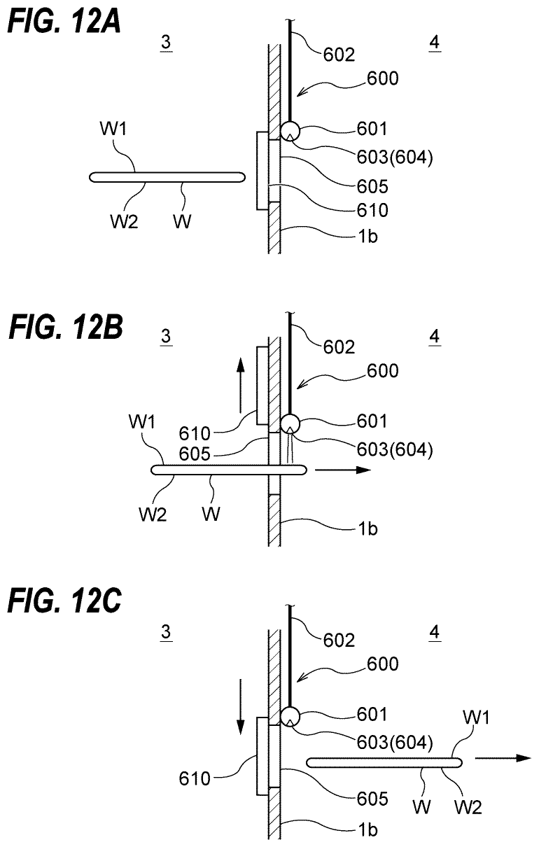

FIGS. 12A to 12C are diagrams showing a wafer W when transported from the polishing section to the cleaning section 4. As shown in FIG. 12A, before the wafer W is transported to the cleaning section 4, the transfer opening 605 is closed by the shutter 610.

As shown in FIG. 12B, when the wafer W is transported from the polishing section 3 to the cleaning section 4, the shutter 610 is opened, so that the wafer W can be transported from the polishing section 3 to the cleaning section 4 through the transfer opening 605. At this time, the fluid ejection device 600 sprays the compressed fluid onto the surface of the wafer W through the ejection ports 603 (or the ejection port 604) of the fluid ejection nozzle 601. The fluid ejection device 600 completely removes the liquid from the surface of the wafer W by spraying the compressed fluid onto the surface of the wafer W.

Thereafter, as shown in FIG. 12C, after the wafer W passes through the transfer opening 605, the shutter 610 is closed and the fluid ejection device 600 stops supplying the compressed fluid from the fluid ejection nozzle 601. In this manner, through the series of processes shown in FIG. 12A to FIG. 12C, the wafer W that has been polished in the polishing section 3 is transported to the cleaning section 4 after the liquid is removed from the surface of the wafer W.

In this embodiment also, when the transfer robot 209 accesses the wafer W on the temporary placement table 180, the controller 5 operates the Z-axis actuator 512 to move the fixed sensor 501A and the movable sensor 501B to a predetermined retreat position, so that the fixed sensor 501A and the movable sensor 501B do not contact the wafer W.

Thereafter, the controller 5 operates the Z-axis actuator 512 to move the fixed sensor 501A and the movable sensor 501B to a predetermined detection position close to the wafer W on the robot hand 520. The fixed sensor 501A and the movable sensor 501B that have been moved to the detection position detect the signal corresponding to the shape of the wafer W while the wafer W is rotated by the transfer robot 209.

More specifically, while the transfer robot 209 is rotating the wafer W, the controller 5 operates the X-axis actuator 510 to move the movable sensor 501B from the periphery PP of the wafer W toward the center CP of the wafer W. The movable sensor 501B detects the signal along the spiral detection path, while the movable sensor 501B makes the linear movement.

The fixed sensor 501A detects the signal corresponding to the shape of the periphery PP of the wafer W during the rotation of the wafer W. After the fixed sensor 501A and the movable sensor 501B detect the signals, the controller 5 operates the Z-axis actuator 512 to move the fixed sensor 501A and the movable sensor 501B to their predetermined retreat positions again.

In one embodiment, the controller 5 may instruct the fixed sensor 501A and the movable sensor 501B to perform the signal detection operation when the transfer robot 209 is transporting the wafer W from a predetermined receiving position (in this embodiment, the temporary placement table 180) to a predetermined transfer position (in this embodiment, the cleaning modules 201A, 201B, 202A, 202B, etc.).

In this embodiment, the shape detection module 500 is coupled to the transfer robot 209. Therefore, the transportation of the wafer W and the signal detection operation can be performed simultaneously, and the throughput of the wafer W can be improved.

As shown in step S202 of FIG. 9, the controller 5 acquires the shape information of the wafer W based on the signals detected by the fixed sensor 501A and the movable sensor 501B, and determines whether or not there is the shape abnormality in the wafer W (see step S203). The flow for determining the shape abnormality in the wafer W is the same as the flow described with reference to the above-mentioned embodiments, and therefore a detailed description thereof will be omitted.

The controller 5 compares the shape information of the wafer W with the predetermined judgment criterion. If the controller determines that no abnormality has occurred in the shape of the wafer W (see “NO” in step S203), the transfer robot 209 transports the wafer W to one of the cleaning modules 201A, 201B, 202A, 202B (see step S204).

On the other hand, if the controller 5 determines that the abnormality has occurred in the shape of the wafer W (see “YES” in step S203), the controller 5 instructs the transfer robot 209 to transport the wafer W to the temporary placement table 203.

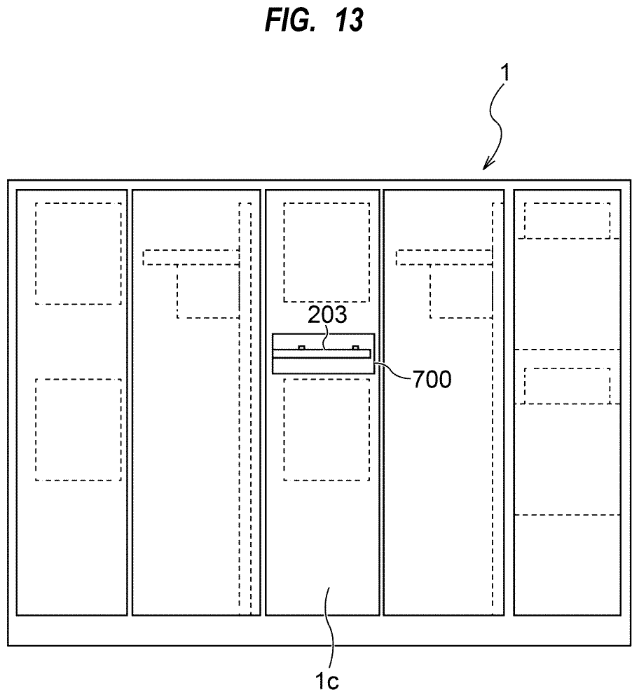

FIG. 13 is a diagram showing a retrieve window through which the temporary placement table can be accessed. As shown in FIG. 13, the substrate processing apparatus has a retrieve window 700 formed in the outer wall 1c of the housing 1. The retrieve window 700 is disposed opposite the temporary placement table 203, so that an operator can access the temporary placement table 203 through the retrieve window 700.

As described above, the controller 5 transports the wafer W having the shape abnormality to the temporary placement table 203. Therefore, the operator can retrieve the wafer W on the temporary placement table 203 through the retrieve window 700 (see step S205). When the controller 5 determines that the wafer W has the shape abnormality, the controller 5 may issue an alarm to notify the operator of the abnormality.

As described with reference to the above embodiments, the substrate processing apparatus includes the shape detection module 400 coupled to the transfer robot 22 and the shape detection module 500 coupled to the transfer robot 209. In one embodiment, the substrate processing apparatus may include a new shape-detection module (not shown) coupled to the transfer robot 210. The new shape-detection module has the same configuration as the shape detection module 500 (or the shape detection module 400). With such a configuration, the controller 5 can determine the shape abnormality of the wafer W that has been cleaned by the cleaning section 4.

In one embodiment, the shape detection modules 400 and 500 may be configured to detect the shape of the same surface (i.e., the first surface W1 or the second surface W2) of the wafer W. Such a configuration can improve the reliability of determining the shape abnormality.

Assuming that the first surface W1 is deformed upward (or downward), the second surface W2 is deformed downward (or upward). In this case, when the shape detection modules 400 and 500 detect the shapes of different surfaces of the wafer W, the controller 5 must calculate the displacement amounts of the wafer W deformed in different directions. In this case, the controller 5 may not be able to accurately determine the shape abnormality of the wafer W.

Therefore, by detecting the shape of the same surface of the wafer W using the shape detection modules 400 and 500, the controller 5 can calculate the displacement amount of the wafer W deformed in the same direction. As a result, the controller 5 can accurately determine the shape abnormality of the wafer W.

In the above-described embodiments, the transfer robot 22 is not configured to rotate the wafer W. Therefore, the shape detection module 400 is configured to detect shape abnormality over the entire surface of the non-rotating wafer W by the detection sensor 401.

On the other hand, the transfer robot 209 is configured to rotate the wafer W. Therefore, the shape detection module 500 is configured to detect the shape abnormality in the entire surface of the rotating wafer W by the fixed sensor 501A and the movable sensor 501B.

It is noted, however, that there is no particular limitation on the specific mechanism of the shape detection modules 400 and 500 as long as both of the shape detection modules 400 and 500 have a mechanism for determining the shape abnormality of the wafer W. For example, the transfer robots 22 and 209 may have the same configuration, and the shape detection modules 400 and 500 may have the same configuration.

In the above-described embodiments, the shape detection module 400 includes the detection sensor 401 as an optical sensor, and the shape detection module 500 includes the fixed sensor 501A and the movable sensor 501B as optical sensors.

In one embodiment, the shape detection module 400 may include an image sensor instead of the optical sensor as the detection sensor 401. Similarly, the shape detection module 500 may include image sensors instead of the optical sensors as the fixed sensor 501A and the movable sensor 501B.

In this case, the controller 5 acquires a signal (image signal) detected by the image sensor, and creates, from the acquired image signal, image data as shape information of the wafer W. The memory 5a stores reference image data to be compared with the image data. Examples of the reference image data include image data of a contour including the periphery PP of the wafer W and image data indicating shade of a shadow over the entire wafer W. The controller 5 compares the image data with the reference image data to determine whether or not the wafer W has the shape abnormality.

In the above-described embodiments, the fixed sensor 501A and the movable sensor 501B are the same sensor, but the fixed sensor 501A and the movable sensor 501B may be different sensors. For example, the fixed sensor 501A as an image sensor may detect the contour of the wafer W including the periphery PP, and the movable sensor 501B as an optical sensor may detect the surface shape of the wafer W inwardly of the periphery PP.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A substrate processing apparatus comprising:
a processing module configured to process a substrate;
a transfer robot configured to transport the substrate to the processing module;
a shape detection module configured to detect a signal corresponding to a surface shape of the substrate held by the transfer robot, the shape detection module being coupled to the transfer robot and configured to detect the signal above the transfer robot; and
a controller configured to determine a shape abnormality of the substrate based on the signal detected by the shape detection module.

2. The substrate processing apparatus according to claim 1, wherein the shape detection module includes:
a detection sensor disposed above the substrate held by the transfer robot; and
a sensor-moving actuator configured to move the detection sensor along a movement path on a surface of the substrate.

3. The substrate processing apparatus according to claim 1, wherein the transfer robot is configured to rotate the substrate, and
the shape detection module includes:
a fixed sensor disposed above a periphery of the substrate held by the transfer robot;
a movable sensor configured to be movable in a direction parallel to the substrate held by the transfer robot; and
a sensor-moving actuator configured to move the movable sensor forward and backward from the periphery to a center of the substrate.

4. The substrate processing apparatus according to claim 1, wherein the shape detection module is configured to detect the signal when the transfer robot is transporting the substrate.

5. The substrate processing apparatus according to claim 1, wherein
the shape detection module comprises a first shape detection module,
the transfer robot comprises a first transfer robot,
the first transfer robot is configured to transport the substrate to a polishing module,
the substrate processing apparatus comprises:
a second transfer robot configured to transport the substrate polished by the polishing module to a cleaning module; and
a second shape detection module coupled to the second transfer robot and configured to detect a signal corresponding to the surface shape of the substrate held by the second transfer robot.

6. The substrate processing apparatus according to claim 5, wherein the first shape detection module and the second shape detection module are configured to detect the shape of the same surface of the substrate.

7. The substrate processing apparatus according to claim 5, further comprising a fluid ejection device disposed on a transport path for the substrate between the polishing module and the cleaning module, the fluid ejection device including a fluid ejection nozzle configured to spray compressed fluid onto a surface of the substrate that is to be detected by the second shape detection module.

8. The substrate processing apparatus according to claim 1, wherein the controller is configured to:
acquire shape information of the substrate to be determined for the shape abnormality based on the signal acquired from the shape detection module; and
compare the acquired shape information with a predetermined judgment criterion to determine the shape abnormality.

9. The substrate processing apparatus according to claim 8, wherein the controller is configured to:
create a normal distribution from a plurality of values calculated based on a plurality of signals previously acquired from the shape detection module; and
determine, as the judgment criterion, a range of ±Xσ from a mean value of the normal distribution.

10. A substrate processing method comprising:
detecting, by a shape detection module, a signal corresponding to a surface shape of a substrate held by a transfer robot that transports the substrate to a processing module, the shape detection module being coupled to the transfer robot and arranged to detect the signal from above the transfer robot; and
determining a shape abnormality of the substrate based on the signal detected by the shape detection module.

11. The substrate processing method according to claim 10, wherein the shape detection module includes:
a detection sensor; and
a sensor-moving actuator configured to move the detection sensor,
wherein the detection sensor is disposed above the substrate held by the transfer robot, and
the sensor-moving actuator moves the detection sensor along a movement path on a surface of the substrate.

12. The substrate processing method according to claim 10, wherein the shape detection module includes:
a fixed sensor and a movable sensor; and
a sensor-moving actuator configured to move the movable sensor forward and backward from a periphery of the substrate to a center of the substrate,
wherein the sensor-moving actuator moves the movable sensor forward and backward from the periphery to the center of the substrate while the substrate is being rotated by the transfer robot.

13. The substrate processing method according to claim 10, wherein the signal is detected by the shape detection module while the substrate is being transported by the transfer robot.

14. The substrate processing method according to claim 10, wherein
the shape detection module comprises a first shape detection module,
the transfer robot comprises a first transfer robot,
the substrate is transported to a polishing module by the first transfer robot,
the substrate polished by the polishing module is transported to a cleaning module by a second transfer robot,
a second shape detection module detects a signal corresponding to the surface shape of the substrate held by the second transfer robot, and
the second shape detection module is coupled to the second transfer robot.

15. The substrate processing method according to claim 14, wherein the first shape detection module and the second shape detection module detect the shape of the same surface of the substrate.

16. The substrate processing method according to claim 14, further comprising spraying, by a fluid ejection device, a compressed fluid onto a surface of the substrate that is to be detected by the second shape detection module, the fluid ejection device being disposed on a transport path for the substrate between the polishing module and the cleaning module.

17. The substrate processing method according to claim 10, further comprising:
acquiring shape information of the substrate to be determined for the shape abnormality based on the signal acquired from the shape detection module; and
comparing the acquired shape information with a predetermined judgment criterion to determine the shape abnormality.

18. The substrate processing method according to claim 17, further comprising:
creating a normal distribution from a plurality of values calculated based on a plurality of signals previously acquired from the shape detection module; and
determining, as the judgment criterion, a range of ±Xσ from a mean value of the normal distribution.
